(19) United States
(12) Patent Application Publication
(10) Pub. No.: US 2024/0319584 A1
(43) Pub. Date: Sep. 26, 2024

(54) FABRICATION OF ANGLED MANDREL STRUCTURES IN SEMICONDUCTOR DEVICE

(71) Applicant: International Business Machines Corporation, Armonk, NY (US)

(72) Inventors: Pouya Hashemi, Purchase, NY (US); Steven Holmes, Red Hook, NY (US); Robert L. Bruce, White Plains, NY (US); Eric A. Joseph, Croton on Hudson, NY (US); Yanning Sun, Scarsdale, NY (US)

(21) Appl. No.: 18/189,185

(22) Filed: Mar. 23, 2023

(51) Int. Cl. G03F 7/00

(52) U.S. Cl. CPC G03F 7/0002; G03F 7/0015; G03F 7/0035

(57) ABSTRACT

A semiconductor structure includes a plurality of mandrel structures disposed above and in contact with a substrate. Each of the plurality of mandrel structures extending outwardly at an inclination angle with respect to a surface plane of the substrate that is different from 90 degrees. A template structure for an imprint mask is formed by the plurality of mandrel structures. The semiconductor structure further includes a layer of a conformal dielectric material covering the plurality of mandrel structures for providing stability and uniformity to the plurality of mandrel structures.

### BACKGROUND

The present invention generally relates to the field of semiconductor devices, and more particularly to nanofabrication techniques and structures.

An artificial reality system, such as a head-mounted display (HMD) or heads-up display (HUD) system, generally includes a display configured to present artificial images that depict objects in a virtual environment. The display may show virtual objects or combine images of real objects with virtual objects, as in virtual reality (VR), augmented reality (AR), or mixed reality (MR) applications. For example, in an AR system, a user may view both images of virtual objects (e.g., computer-generated images (CGIs)) and the surrounding environment by, for example, seeing through transparent display glasses or lenses (often referred to as optical see-through) or viewing displayed images of the surrounding environment captured by a camera (often referred to as video see-through). The optical components are arranged to transport light of the desired image, where the light is generated on the display to the user's eye to make the image visible to the user. The display where the image is generated can form part of a light engine, so the image generates collimated light beams guided by the optical component to provide an image visible to the user.

In some implementations, the light of the projected images may be coupled into or out of the waveguide using a diffractive optical element, such as a slanted surface-relief grating. Slanted gratings show high efficiency in coupling light into waveguides. However, fabrication of master molds used for producing slanted gratings require high etch selectivity between SiO₂ and a metal mask. Additionally, the industry standard for trench etch, reactive ion etching (RIE), cannot produce slanted trenches, and other techniques such as reactive ion beam etching (RIBE) can only produce slanted trenches at a single angle and at a single direction. Therefore, there is a need for improved designs and techniques for producing slanted trench features within a substrate.

### SUMMARY

According to an embodiment of the present disclosure, a semiconductor structure includes a plurality of mandrel structures disposed above and in contact with a substrate, each of the plurality of mandrel structures extending outwardly at an inclination angle with respect to a surface plane of the substrate that is different from 90 degrees, and a template structure for an imprint mask formed by the plurality of mandrel structures. The semiconductor structure further includes a layer of a conformal dielectric material covering the plurality of mandrel structures, the layer of conformal dielectric material providing stability and uniformity to the plurality of mandrel structures. In an embodiment, each of the plurality of mandrel structures has a similar inclination angle with respect to the substrate. In another embodiment, each of the plurality of mandrel structures has a different inclination angle with respect to the substrate.

According to another embodiment of the present disclosure, a method of forming a semiconductor structure includes forming a plurality of mandrel structures above and in in contact with a substrate, each of the plurality of mandrel structures extending outwardly at an inclination angle with respect to a surface plane of the substrate that is different from 90 degrees, the plurality of mandrel structures providing a template structure for an imprint mask. The method further includes forming a layer of a conformal dielectric material to cover the plurality of mandrel structures, the layer of conformal dielectric material providing stability and uniformity to the plurality of mandrel structures. In an embodiment, each of the plurality of mandrel structures has a similar inclination angle with respect to the substrate. In another embodiment, each of the plurality of mandrel structures has a different inclination angle with respect to the substrate.

### BRIEF DESCRIPTION OF THE DRAWINGS

The following detailed description, given by way of example and not intended to limit the invention solely thereto, will best be appreciated in conjunction with the accompanying drawings, in which:

FIG. 1A is a cross-sectional view of a first semiconductor structure at an intermediate step during a semiconductor manufacturing process, according to an embodiment of the present disclosure;

FIG. 1B is a cross-sectional view of the first semiconductor structure depicting forming a mask layer and conducting an etching process, according to an embodiment of the present disclosure;

FIG. 1C is a cross-sectional view of the first semiconductor structure depicting conducting an ion implantation process, according to an embodiment of the present disclosure;

FIG. 1D is a cross-sectional view of the first semiconductor structure depicting forming a form a doped region, according to an embodiment of the present disclosure;

FIG. 1E is a cross-sectional view of the first semiconductor structure depicting selectively removing a remaining portion of a silicon-on-insulator layer, according to an embodiment of the present disclosure;

FIG. 2A is a cross-sectional view of a second semiconductor structure depicting a starting semiconductor substrate, according to an embodiment of the present disclosure;

FIG. 2B is a cross-sectional view of the second semiconductor structure depicting forming a first hardmask layer and conducting an etching process, according to an embodiment of the present disclosure;

FIG. 2C is a cross-sectional view of the second semiconductor structure depicting forming a first epitaxial layer, according to an embodiment of the present disclosure;

FIG. 2D is a cross-sectional view of the second semiconductor structure depicting selectively removing the first hardmask layer and the silicon-on-insulator layer, according to an embodiment of the present disclosure;

FIG. 2E is a cross-sectional view of the second semiconductor structure depicting forming a block mask, according to an embodiment of the present disclosure;

FIG. 2F is a cross-sectional view of the second semiconductor structure depicting etching selected portions of the first epitaxial layer located above a buried oxide layer, according to an embodiment of the present disclosure;

FIG. 3A is a cross-sectional view of a third semiconductor structure depicting a starting semiconductor substrate, according to an embodiment of the present disclosure;

FIG. 3B is a cross-sectional view of the third semiconductor structure depicting forming a second epitaxial layer, according to an embodiment of the present disclosure;

FIG. 3C is a cross-sectional view of the third semiconductor structure depicting forming a second hardmask layer and patterning the second epitaxial layer, according to an embodiment of the present disclosure;

FIG. 3D is a cross-sectional view of the third semiconductor structure depicting selectively etching the second epitaxial layer, according to an embodiment of the present disclosure;

FIG. 3E is a cross-sectional view of the third semiconductor structure depicting conducting a high temperature anneal process, according to an embodiment of the present disclosure;

FIG. 3F is a cross-sectional view of the third semiconductor structure depicting forming a third epitaxial layer, according to an embodiment of the present disclosure;

FIG. 3G is a cross-sectional view of the third semiconductor structure depicting selectively removing the second hardmask layer and the second epitaxial layer, according to an embodiment of the present disclosure;

FIG. 3H is a cross-sectional view of the third semiconductor structure depicting masking selected portions of the third epitaxial layer, according to an embodiment of the present disclosure;

FIG. 3I is a cross-sectional view of the third semiconductor structure depicting etching uncovered portions of the third epitaxial layer, according to an embodiment of the present disclosure;

FIG. 4A is a cross-sectional view of a fourth semiconductor structure depicting a starting semiconductor substrate, according to an embodiment of the present disclosure;

FIG. 4B is a cross-sectional view of the fourth semiconductor structure depicting forming a fourth epitaxial layer, according to an embodiment of the present disclosure;

FIG. 4C is a cross-sectional view of the fourth semiconductor structure depicting forming a third hardmask layer and patterning the fourth epitaxial layer, according to an embodiment of the present disclosure;

FIG. 4D is a cross-sectional view of the fourth semiconductor structure depicting forming a sidewall spacer and recessing a base substrate, according to an embodiment of the present disclosure;

FIG. 4E is a cross-sectional view of the fourth semiconductor structure depicting forming a fifth epitaxial layer, according to an embodiment of the present disclosure;

FIG. 4F is a cross-sectional view of the fourth semiconductor structure depicting conducting a planarization process, according to an embodiment of the present disclosure;

FIG. 4G is a cross-sectional view of the fourth semiconductor structure depicting forming a fourth hardmask layer, according to an embodiment of the present disclosure;

FIG. 4H is a cross-sectional view of the fourth semiconductor structure depicting simultaneously patterning the fourth epitaxial layer and the fifth epitaxial layer, according to an embodiment of the present disclosure;

FIG. 4I is a cross-sectional view of the fourth semiconductor structure depicting conducting an etching process to selectively recess the fourth epitaxial layer and the fifth epitaxial layer, according to an embodiment of the present disclosure; and

FIG. 4J is a cross-sectional view of the fourth semiconductor structure depicting removing the fourth hardmask layer, according to an embodiment of the present disclosure.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Fabrication of slanted or angled trench features vertically into a substrate are needed for augmented reality (AR) devices. Current state-of-the-art technology uses reactive ion beam etching (RIBE) at an angle to form such features by means of tilting the entire wafer inside the etch chamber. In such a system, only single angle trench features at a single direction can be formed on the substrate. Moreover, the use of reactive ion beam etching for forming angled features for augmented reality displays may hinder reaching a needed depth due to redeposition issues during the etch process and low selectivity of the etch mask. In some cases, the critical dimension (CD) and profile control of angled mandrel structures that are used as mold can also be degraded by the redeposition issues.

As a result, it may be desired to form mandrel structures at a variety of different angles and at a variety of different orientations (e.g., X and Y orientations) on the same substrate at the same time such that the mandrel structures can be used as a mold for nanoimprint lithography (NIL) for forming angled trench features. Wafer-level NIL has increasingly become a key enabling technology to support AR devices, optical sensors, and biomedical chips, among other technologies. NIL may allow mass manufacture of micro- and nano-scale structures with a maximum degree of freedom for the device dimensions. Another key advantage of this replication-based technology is, given by the fact that even complex structures which require precise and time-consuming fabrication methods can be transferred to mass manufacturing in an efficient semiconductor manufacturing line. Additionally, for many devices especially for optical applications the replicated layer can be directly used as functional layer in the product.

Therefore, embodiments of the present disclosure provide a semiconductor structure, and a method of making the same, including a plurality of angled mandrel structures suitable for making an imprint mask for nanoimprint lithography. Specifically, embodiments of the present disclosure use boron-doped silicon, graded silicon-germanium films, and inversely graded silicon-germanium films separated by sidewall spacers to selectively create asymmetric mandrel profiles that can be used as a template structure for making an imprint hardmask.

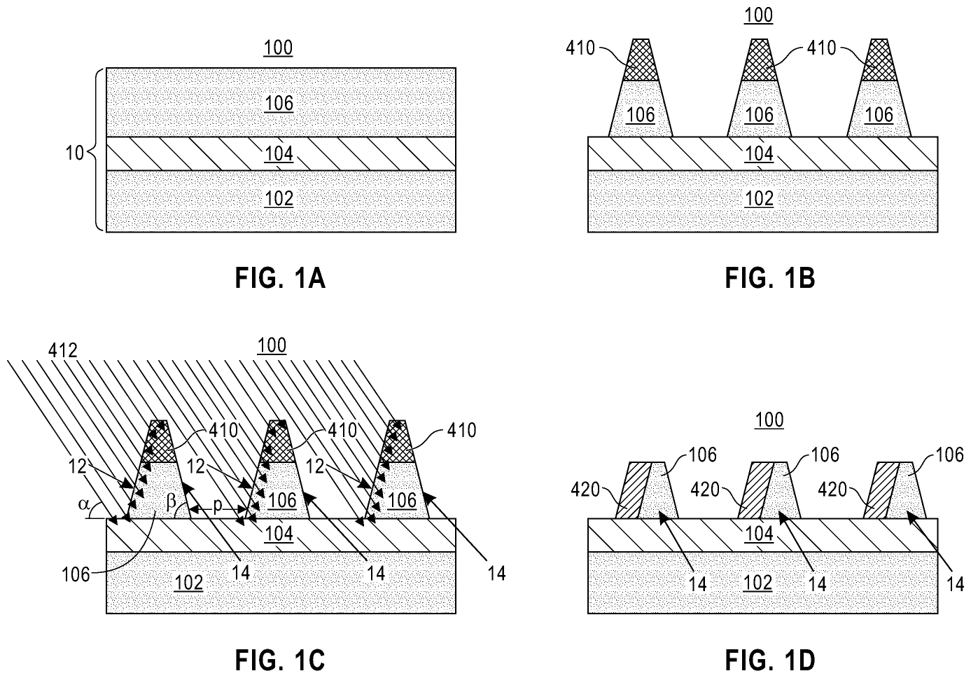

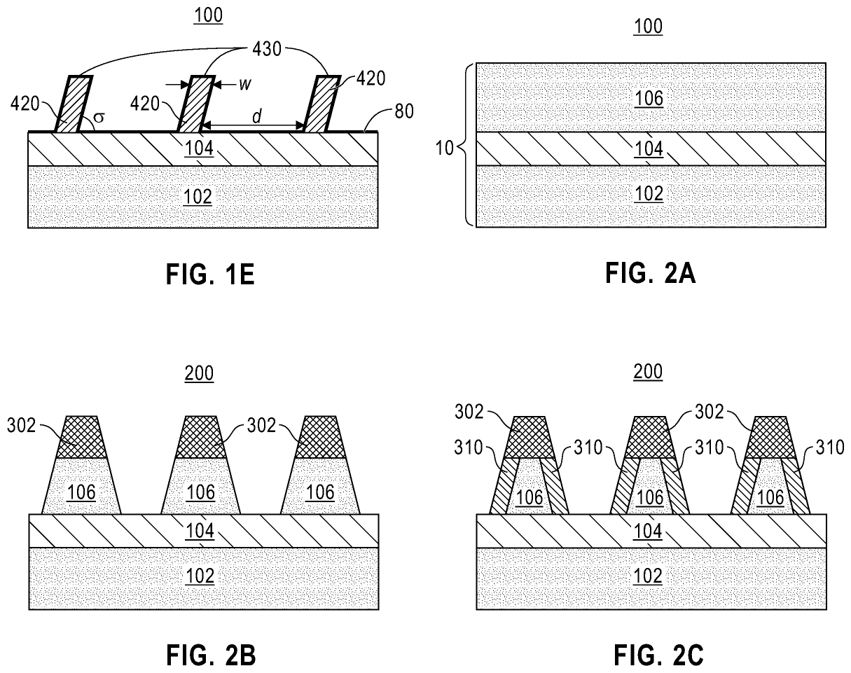

Embodiments by which the angled mandrel structures can be formed are described in detailed below by referring to the accompanying drawings in FIGS. 1A-4E.

Referring now to FIG. 1A, a cross-sectional view of a first semiconductor structure 100 at an intermediate step during a semiconductor manufacturing process is shown, according to an embodiment of the present disclosure.

At this step of the semiconductor manufacturing process, the first semiconductor structure 100 includes a substrate 10 that may be a silicon-on-insulator (SOI) substrate. In embodiments in which the substrate 10 is an SOI substrate, the substrate 10 is typically composed of a base substrate 102, a buried dielectric layer 104 (e.g., buried oxide) formed on top of the base substrate 102, and a SOI layer 106 formed on top of the buried dielectric layer 104. According to an embodiment, the buried dielectric layer 104 and the SOI layer 106 are vertically stacked one on top of another in a direction perpendicular to the base substrate 102, as illustrated in the figure. The buried dielectric layer 104 isolates the SOI layer 106 from the base substrate 102.

The base substrate 102 may be made from any of several known semiconductor materials such as, for example, silicon, poly-crystalline silicon, amorphous silicon, germanium, silicon-germanium alloy, poly-crystalline silicon-germanium, amorphous silicon-germanium, silicon carbide, silicon-germanium carbide alloy, and compound (e.g., III-V and II-VI) semiconductor materials. Non-limiting examples of compound semiconductor materials include gallium arsenide, indium arsenide, and indium phosphide. Typically, the base substrate 102 may be about, but is not limited to, several hundred microns thick. For example, the base substrate 102 may include a thickness ranging from 0.5 mm to about 1.5 mm. In some embodiments, the base substrate 102 may be, for example, a bulk substrate.

The buried dielectric layer 104 may be formed from any of several known dielectric materials. Non-limiting examples include, for example, oxides, nitrides and oxynitrides of silicon. Oxides, nitrides and oxynitrides of other elements are also envisioned. In addition, the buried dielectric layer 104 may include a crystalline or non-crystalline dielectric material. Moreover, the buried dielectric layer 104 may be formed using any of several known methods. Non-limiting examples include ion implantation methods, thermal or plasma oxidation or nitridation methods, chemical vapor deposition methods and physical vapor deposition methods. The buried dielectric layer 104 may include a thickness ranging from approximately 20 nm to approximately 100 nm, and ranges therebetween.

The SOI layer 106 may include any of the several semiconductor materials included in the base substrate 102. In general, the base substrate 102 and the SOI layer 106 may be made of either identical or different semiconductor materials with respect to chemical composition, dopant concentration and crystallographic orientation. In an embodiment of the present invention, the base substrate 102 and the SOI layer 106 are made of silicon. The SOI layer 106 may have a thickness varying preferably from approximately 250 nm to approximately 300 nm. Although, in some embodiments, the SOI layer 106 may have a thickness of up to 500 nm. As may be known by those skilled in the art, in some embodiments, the SOI layer 106 may be entirely consumed during subsequent patterning processes. Methods for forming the SOI layer 106 are well known in the art and will not be described in detail herein to avoid unnecessarily obscuring the presented embodiments.

Referring now to FIG. 1B, a cross-sectional view of the first semiconductor structure 100 is shown after forming a mask layer 410 and conducting an etching process, according to an embodiment of the present disclosure.

The mask layer 410 is formed above and in direct contact with the SOI layer 106. In one or more embodiments, the mask layer 410 may be a hard mask composed of a dielectric material such as, for example, silicon dioxide, silicon nitride, silicon carbide, or a combination of such materials forming a multiple stack hardmask. Any known dielectric deposition process can be conducted to form the mask layer 410.

In other embodiments, the mask layer 410 may be a soft mask made of any organic planarizing material that is capable of effectively preventing damage of underlying layers during subsequent etching processes. In such embodiments, the mask layer 410 can include, but is not necessarily limited to, an organic polymer including C, H, and N. According to an embodiment, the organic planarizing material can be free of silicon (Si). According to another embodiment, the organic planarizing material can be free of Si and fluorine (F). As defined herein, a material is free of an atomic element when the level of the atomic element in the material is at or below a trace level detectable with analytic methods available in the art. Non-limiting examples of organic planarizing material for forming the mask layer 410 may include JSR HM8006, JSR HM8014, AZ UM10M2, Shin Etsu ODL 102, or other similar commercially available materials. The mask layer 410 may be deposited by, for example, spin coating followed by a planarization process, such as a chemical mechanical polishing (CMP).

A thickness of the mask layer 410 may vary from approximately 50 nm to approximately 1000 nm and ranges therebetween, although a thickness less than 50 nm and greater than 200 nm may be acceptable.

With continued reference to FIG. 1B, a lithography process can be conducted on the mask layer 410 followed by a reactive ion etch (RIE) to achieve tapered sidewalls in the SOI layer 106, as depicted in the figure. More particularly, after the lithography and RIE processes, the SOI layer 106 is divided into a plurality of sections with angled or tapered sidewalls. In the depicted embodiment, the remaining sections of the SOI layer 106 include a reverse tapered profile in which a width or critical dimension (CD) of a top portion of each section of the SOI layer 106 is larger than a width or CD of a bottom portion of each section of the SOI layer 106. Stated differently, after conducting the lithography process, the width or CD of each section of the SOI layer 106 increases towards the buried dielectric layer 104, as shown in the figures.

Referring now to FIGS. 1C-1D simultaneously, cross-sectional views of the first semiconductor structure 100 are shown after conducting an ion implantation process on the SOI layer 106 to form a doped region 420, according to an embodiment of the present disclosure.

In this embodiment, an angled ion implantation 412 can be conducted on the semiconductor structure 100 to introduce dopants to a first surface 12 of the SOI layer 106. A second surface 14 of the SOI layer 106 opposing the first surface 12 is substantially free of dopants.

In a preferred embodiment, the dopants are composed of boron. It is noted that other dopants are also contemplated and are within the scope of the invention, so long as the dopants allow for selective etching between the doped region 420 in which the dopants are present and the second surface 14 of the SOI layer 106 that is substantially free of the dopants.

Angled ion implantation 412 implants dopants towards a surface of the first surface 12 of the SOI layer 106 forming an implantation angle α with the horizontal plane. In one or more embodiments, the implantation angle α is less or equal than an inclination angle b (α≤b) of a sidewall of the SOI layer 106 corresponding to the second surface 14. In addition, the minimum angle α is governed by the pitch p of the patterned SOI layer 106 and shadowing effect by the neighboring SOI layer 106 pillars to ensure the ions reach out a bottom surface of the first surface 12 of the SOI layer 106 depicted in FIG. 1C. In an embodiment, the angled ion implantation 412 can be conducted at an implantation angle α ranging from approximately 250 to approximately 75°. In another embodiment, the angled ion implantation 412 includes an implantation angle α ranging from approximately 400 to approximately 60°.

In an embodiment, the angled ion implantation 412 may include a boron dopant and may employ an implant having an ion dosage ranging from 1×10¹³ atoms/cm² to 5×10¹⁵ atoms/cm². Thus, the dopant concentration in the doped region 420 may range from approximately 1×10¹⁸ atoms/cm³ to approximately 8×10²¹ atoms/cm³. In another embodiment, the dopant concentration in the doped region 420 may vary from approximately 1×10¹⁹ atoms/cm³ to approximately 3×10²⁰ atoms/cm³. Preferably, the dopant concentration in the doped region 420 ranges from approximately 3×10¹⁹ atoms/cm³ to approximately 1×10²⁰ atoms/cm³.

In an exemplary embodiment, the angled ion implantation 412 may be carried out using an ion implant apparatus that operates at an energy ranging from approximately 5.0 keV to approximately 60.0 keV. In another embodiment, the angled ion implantation 412 may be carried out using an energy varying from approximately 10.0 keV to approximately 40.0 keV. The angled ion implantation may be carried out at a temperature ranging from approximately 50° C. to approximately 500° C. In another embodiment, the angled ion implantation is carried out with a temperature ranging from approximately 100° C. to approximately 300° C.

The term “substantially free of the dopants” as used to describe the remaining (second) surface 14 of the SOI layer 106 means that the dopant concentration is less than approximately 1×10¹⁶ atoms/cm³.

After conducting the angled ion implantation 412 and forming the doped region 420, the mask layer 410 can be removed from the first semiconductor structure 100 using a selective wet or dry etch process.

Referring now to FIG. 1E, a cross-sectional view of the first semiconductor structure 100 is shown after selectively removing a remaining portion of the SOI layer 106 depicted in FIG. 1D, according to an embodiment of the present disclosure.

Remaining portions of the SOI layer 106 (FIG. 1D) corresponding to the second surface 14 (FIG. 1D) can be selectively removed with respect to the buried dielectric layer 104 and doped region 420 using, for example, a HCl chemistry in an epitaxial or rapid thermal chemical vapor deposition (RTCVD) reactor. Thus, in the depicted embodiment, the doped regions 420 disposed above the buried dielectric layer 104 provide a first plurality of mandrel structures 430 (hereinafter “first mandrel structures”) that can be used as a mold for nanoimprint lithography and/or as optical waveguides in augmented reality displays.

For illustration purposes only, without intent of limitation, only three first mandrel structures 430 are shown in the figures. It should be noted that any number of first mandrel structures 430 can be formed in the first semiconductor structure 100 to satisfy design requirements. It should also be noted that an inclination angle s (with respect to the horizontal plane) of the first mandrel structures 430 can be tailored to satisfy design requirements by adjusting operational parameters of the tapered RIE described in FIG. 1B and operational parameters of the angled ion implantation 412. Thus, the first mandrel structures 430 extend outwardly at an inclination angle s with respect to a surface plane of the substrate that is different from 90 degrees. Although not depicted in the figures, the first mandrel structures 430 may have one or more different inclination angles s different from 90 degrees.

Alternatively, or additionally, the first mandrel structures 430 may be covered with a thin layer of a conformal dielectric material 80 such as, for example, SiO₂ or SiN for stability and uniformity purposes. The thin layer of conformal dielectric material 80 may have a thickness varying from approximately 5 to approximately 20 nm, and ranges therebetween, and can be deposited using any conformal deposition process including, but not limited to, CVD, PECVD or ALD.

According to an embodiment, a distance d (i.e., pitch) between first mandrel structures 430 may vary from approximately 100 nm to approximately 2000 nm. In another embodiment, the distance d between the first mandrel structures 430 may vary from approximately 200 nm to approximately 1000 nm, although other distances are within the contemplated scope of the invention. In one or more embodiments, the first mandrel structures 430 may have a width w determined by a depth of the angled ion implantation 412. In an exemplary embodiment, the width w may vary from approximately 50 nm to approximately 500 nm, and ranges therebetween. In another embodiment, the width w may vary from approximately 100 nm to approximately 300 nm.

Thus, in this embodiment, an angled ion implantation is conducted into a vertically etched silicon mandrel to reduce the solubility of the implanted silicon in aqueous base (e.g., KOH), the unimplanted silicon is etched leaving an angled structure in place. In this embodiment, the width of the first mandrel structures is determined by the depth of the implant. The resulting doped silicon mandrel structures (i.e., first mandrel structures 430) include an inclination angle with respect to the horizontal plane and high CD uniformity since the mandrels CD is determined by the implant depth.

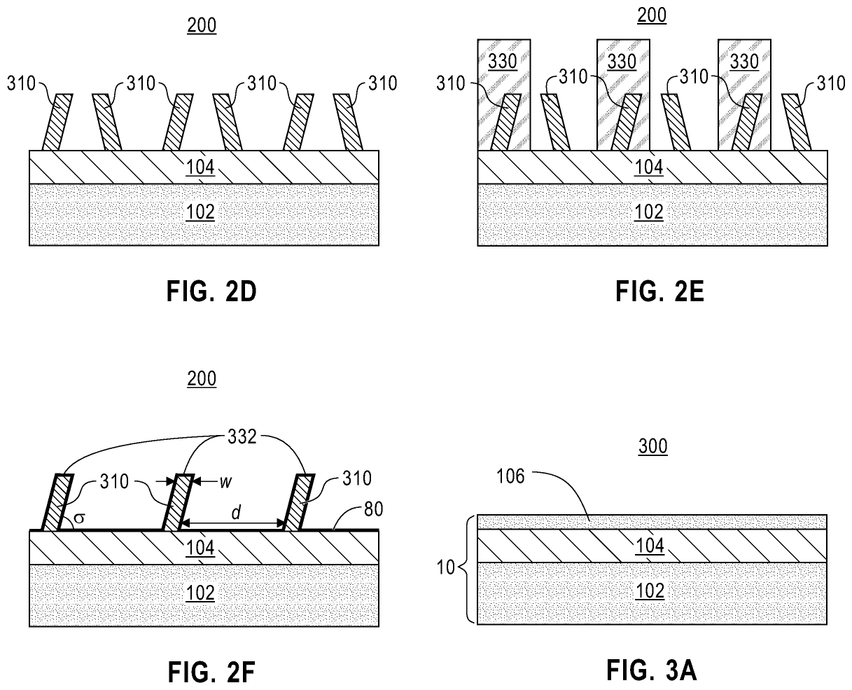

Another embodiment by which angled mandrel structures can be formed is described in detailed below by referring to the accompanying drawings in FIGS. 2A-2F.

Referring now to FIGS. 2A-2B simultaneously, cross-sectional views of a second semiconductor structure 200 are shown after forming a first hardmask layer 410 and conducting an etching process, according to an embodiment of the present disclosure.

As depicted in FIG. 2A, the initial second semiconductor structure 200 includes the same components as the first semiconductor structure 100 shown in FIG. 1A. Thus, in the interest of not obscuring the presentation of embodiments of the present invention, processing steps or operations that are known in the art or have been previously described may have been combined together for presentation and for illustration purposes and in some instances may have not been described in detail. In other instances, processing steps or operations that are known in the art or have been previously explained may not be described at all. It should be understood that the following description is rather focused on the distinctive features or elements of various embodiments of the present invention.

With reference now to FIG. 2B, a first hardmask layer 302 is formed above and in direct contact with the SOI layer 106. In one or more embodiments, the first hardmask layer 302 is composed of a dielectric material such as, for example, silicon dioxide, silicon nitride, silicon carbide, or a combination of such materials forming a multiple stack hardmask. Any known dielectric deposition process can be conducted to form the first hardmask layer 302. In an exemplary embodiment, a thickness of the first hardmask layer 302 may vary from approximately 50 nm to approximately 1000 nm and ranges therebetween, although a thickness less than 50 nm and greater than 200 nm may be acceptable.

A lithography process can be conducted on the first hardmask layer 302 followed by a RIE process to achieve tapered sidewalls in the SOI layer 106, as depicted in the figure. More particularly, after the lithography and RIE processes, the SOI layer 106 is divided into a plurality of sections or pillars with angled or tapered sidewalls. Similar to the first semiconductor structure 100 depicted in FIG. 1B, remaining sections of the SOI layer 106 in the second semiconductor structure 200 include a reverse tapered profile in which a width or CD of a top portion of each section of the SOI layer 106 is larger than a width or CD of a bottom portion of each section of the SOI layer 106. Stated differently, after conducting the lithography process, the width or CD of each section of the SOI layer 106 increases towards the buried dielectric layer 104. It should be noted that, in the depicted embodiment, a tapered profile of the SOI layer 106 may be wider than a tapered profile of the SOI layer 106 depicted in FIG. 1B.

Referring now to FIG. 2C, a cross-sectional view of the second semiconductor structure 200 is shown after forming a first epitaxial layer 310 on opposing sidewalls of the SOI layer 106, according to an embodiment of the present disclosure.

The first epitaxial layer 310 may be formed off the SOI layer 106 using an epitaxial growth process. In one or more embodiments, the first epitaxial layer 310 includes silicon-germanium (SiGe). Prior to forming the first epitaxial layer 310, the SOI layer may be recessed using any suitable etching process including, for example, an isotropic reactive ion etch or a wet or dry oxidation process such as thermal or plasma oxidation or cyclic NH₄:H₂O₂:H₂O followed by removal of the formed silicon dioxide by diluted hydrofluoric acid. In one or more embodiments, the first epitaxial layer 310 can be grown to a thickness varying from approximately 30 nm to approximately 150 nm, although other thicknesses are within the contemplated scope of the invention. Preferably, the first epitaxial layer 310 is grown to a thickness varying from approximately 30 nm to approximately 150 nm.

In general, the first epitaxial layer 310 can be formed by epitaxial growth by using the recessed SOI layer 106 as the seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same or substantially similar crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Non-limiting examples of various epitaxial growth processes include rapid thermal chemical vapor deposition (RTCVD), low-energy plasma deposition (LEPD), ultra-high vacuum chemical vapor deposition (UHVCVD), atmospheric pressure chemical vapor deposition (APCVD), metalorganic chemical vapor deposition (MOCVD), low-pressure chemical vapor deposition (LPCVD), limited reaction processing CVD (LRPCVD), and molecular beam epitaxy (MBE). The temperature for an epitaxial deposition process can range from 300° C. to 900° C. Although higher temperatures typically result in faster deposition, the faster deposition may result in crystal defects and film cracking.

Several different precursors may be used for the epitaxial growth of the first epitaxial layer 310. In some embodiments, a gas source for the deposition of epitaxial semiconductor material includes a silicon containing gas source, a germanium containing gas source, or a combination thereof. For example, an epitaxial silicon layer may be deposited from a silicon gas source including, but not necessarily limited to, silane, disilane, trisilane, tetrasilane, hexachlorodisilane, tetrachlorosilane, dichlorosilane, trichlorosilane, and combinations thereof. An epitaxial germanium layer can be deposited from a germanium gas source including, but not necessarily limited to, germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, helium and argon can be used.

Referring now to FIG. 2D, a cross-sectional view of the second semiconductor structure 200 is shown after selectively removing the first hardmask layer 302 and the SOI layer 106 depicted in FIG. 2C, according to an embodiment of the present disclosure.

The first hardmask layer 302 and the SOI layer 106 can be removed from the second semiconductor structure 200 selective to the first epitaxial layer 310. For example, a wet etch process utilizing a TMAH (tetra-methyl-ammonium-hydroxide) solution can be used to selectively remove the silicon-containing SOI layer 106 with respect to the silicon-germanium-containing first epitaxial layer 310.

Referring now to FIGS. 2E-2F simultaneously, cross-sectional views of the second semiconductor structure 200 are shown after forming a block mask 330 and selectively removing sections of the first epitaxial layer 310, according to an embodiment of the present disclosure.

In one or more embodiments, the process continues by depositing and lithographically defining a photoresist layer on selected sections or pillars of the first epitaxial layer 310 to form a block mask 330; and selectively etching uncovered sections of the first epitaxial layer 310 using the block mask 330. After selectively removing the uncovered sections of the first epitaxial layer 310, the block mask 330 can be removed using any photoresist striping method known in the art including, for example, plasma ashing.

Accordingly, in the depicted embodiment, sections of the first epitaxial layer 310 disposed above the buried dielectric layer 104 provide a second plurality of mandrel structures 332 (hereinafter “second mandrel structures”) that can be used as a mold for nanoimprint lithography and or optical waveguides in augmented reality displays.

For illustration purposes only, without intent of limitation, only three second mandrel structures 332 are shown in the figures. It should be noted that any number of second mandrel structures 332 can be formed in the second semiconductor structure 200 to satisfy design requirements. It should also be noted that an inclination angle s (with respect to the horizontal plane) of the second mandrel structures 332 can be tailored to satisfy design requirements by adjusting operational parameters of the tapered RIE described in FIG. 2B and operational parameters of the epitaxial growth process used to form the first epitaxial layer 310. Although not depicted in the figures, the second mandrel structures 332 may have one or more different inclination angles s different from 90 degrees.

Similar to the first mandrel structures 430, the second mandrel structures 332 may be covered with a thin layer of a conformal dielectric material 80 such as, for example, SiO₂ or SiN for stability and uniformity purposes. The thin layer of conformal dielectric material 80 may have a thickness varying from approximately 5 to approximately 20 nm, and ranges therebetween, and can be deposited using any conformal deposition process including, but not limited to, CVD, PECVD or ALD.

According to an embodiment, a distance d (i.e., pitch) between second mandrel structures 332 may vary from approximately 200 nm to approximately 2000 nm. In another embodiment, the distance d between the second mandrel structures 332 may vary from approximately 400 nm to approximately 1000 nm, although other distances are within the contemplated scope of the invention.

Thus, in this embodiment, by epitaxially growing a layer of SiGe on an angled Si mandrel, an angled SiGe mandrel structure of well controlled width w can be formed on a semiconductor substrate. After etching the Si mandrel, an angled mandrel structure remains in place (i.e., second mandrel structures 332). The width w of the SiGe second mandrel structures 332 is determined by the amount of initial recess of the SOI layer 106 under the first hardmask layer 302 described in FIG. 2C as well as the epi growth.

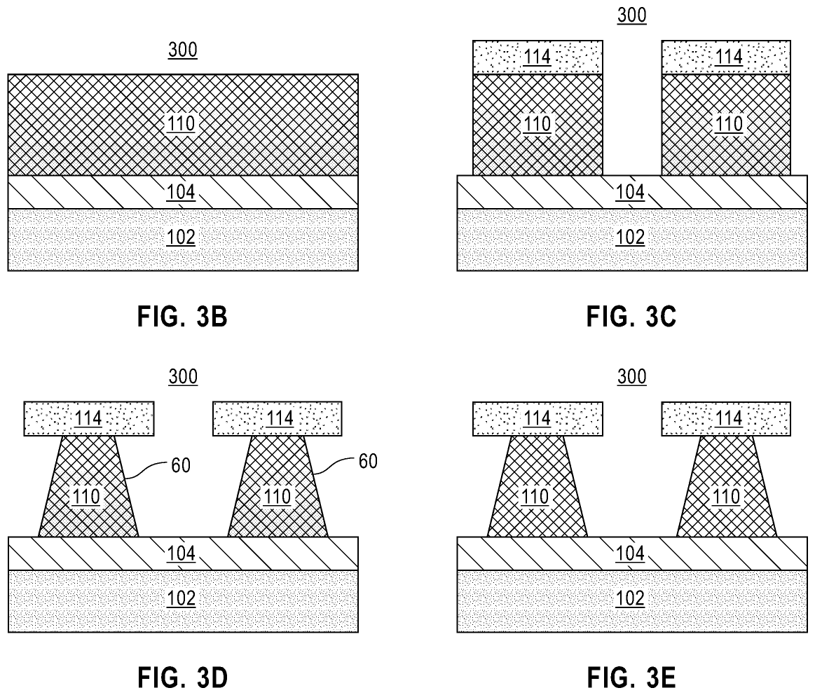

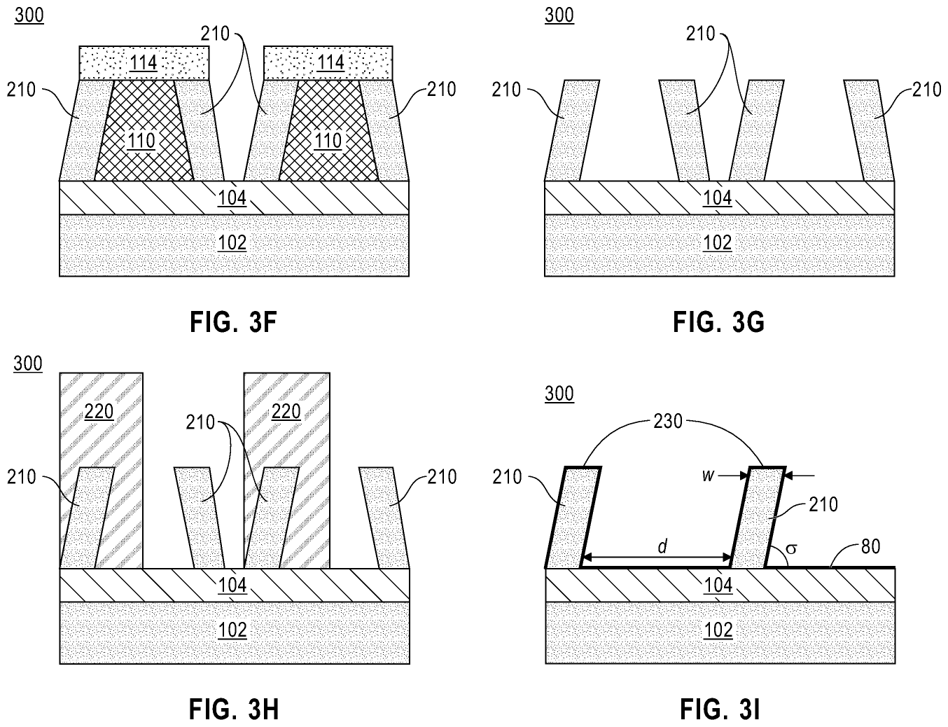

Another embodiment by which angled mandrel structures can be formed is described in detailed below by referring to the accompanying drawings in FIGS. 3A-3I.

Referring now to FIGS. 3A-3B simultaneously, cross-sectional views of a third semiconductor structure 300 are shown after forming a second epitaxial layer 110 above the buried dielectric layer 104, according to an embodiment of the present disclosure.

In this embodiment, the initial semiconductor structure depicted in FIG. 3A is substantially similar to the one described above with reference to FIG. 1A. However, in this instance, the SOI layer 106 have been thinned using, for example, an oxidation process followed by DHF cleaning. Accordingly, in the depicted embodiment, a thickness of the SOI layer 106 may vary from approximately 1 nm to approximately 10 nm, and ranges therebetween. The substantially thin SOI layer 106 may function as a seed layer for the epitaxial growth process conducted to form the second epitaxial layer 110.

The process of epitaxially growing the second epitaxial layer 110 includes similar steps as those used to form the first epitaxial layer 310 described above in FIG. 2C. However, in this embodiment, the second epitaxial layer 110 is a graded layer (a layer that includes two or more materials, the materials having a different ratio at top and the bottom ends of said layer). By grading the second epitaxial layer 110, the number of defects within the layer can be reduced.

In one embodiment, the second epitaxial layer 110 includes a silicon-germanium layer that is linearly graded, e.g., Si₁₋ₓGeₓ. The concentration of germanium atoms is higher at the top end of the second epitaxial layer 110 and lower at the bottom end of the second epitaxial layer 110. In a linearly graded layer, the chemical composition varies continuously, and every horizontal slice of the layer can yield a different composition. The degree of similarity between proximate slices depends upon the thickness of the layer and the degree of change in chemical composition between the top and bottom ends of the layer. In an exemplary embodiment, the second epitaxial layer 110 may be epitaxially grown to a thickness varying between approximately 100 nm and 500 nm, although other thicknesses are within the contemplated scope of the invention. Preferably, the second epitaxial layer 110 is grown to a thickness varying between approximately 300 nm and 400 nm.

For example, in one particular embodiment, the second epitaxial layer 110 can have 100% Si and 0% Ge where it contacts the SOI layer 106. The second epitaxial layer 110 can be graded gradually, such that it has about 20% to 60% Si and 80% to 40% Ge at the top end of the second epitaxial layer 110. In one embodiment, the second epitaxial layer 110 includes a SiGe layer that is graded gradually from 100% Si at the bottom end to 40% Si at the top end of the second epitaxial layer 110.

Referring now to FIGS. 3C-3E simultaneously, cross-sectional views of the third semiconductor structure 300 are shown after forming a second hardmask layer 114 above the second epitaxial layer 110, selectively etching the second epitaxial layer 110 and conducting a high temperature anneal process, according to an embodiment of the present disclosure.

The second hardmask layer 114 is formed above and in direct contact with the second epitaxial layer 110. Similar to the first hardmask layer 302, the second hardmask layer 114 is composed of a dielectric material such as, for example, silicon dioxide, silicon nitride, silicon carbide, or a combination of such materials forming a multiple stack hardmask. Any known dielectric deposition process can be conducted to form the second hardmask layer 114. In an exemplary embodiment, a thickness of the second hardmask layer 114 may vary from approximately 10 nm to approximately 200 nm and ranges therebetween, although a thickness less than 10 nm and greater than 200 nm may be acceptable. The second epitaxial layer 110 can be subsequently etched selective to the second hardmask layer 114 and buried dielectric layer 104. For example, a RIE process can be used to selectively etch the second epitaxial layer 110, as configured in FIG. 3C.

The process continues by selectively recessing the second epitaxial layer 110 with respect to silicon and the second hardmask layer 114 using, for example a high temperature HCl etching in RTCVD reactor. Such process etches SiGe with etch rates proportional to the Ge fraction in the second epitaxial layer 110 forming the trapezoid-like structures 60 depicted in FIG. 3D.

After etching the second epitaxial layer 110, a high temperature anneal process can be conducted on the third semiconductor structure 300 to make the germanium concentration uniform across the second epitaxial layer 110. In an exemplary embodiment, the high-temperature annealing can be conducted at a temperature ranging from approximately 800° C. to approximately 1150° C., although other temperatures are within the contemplated scope of the invention. Preferably, the high-temperature annealing is conducted at 1000° C. In one or more embodiments, a thin sacrificial dielectric deposition around the entire structure 60 may help preserve the structure 60 during the high temperature anneal and avoid unwanted SiGe deformation. This sacrificial dielectric (such as thin SiO₂ or SiN) can then be removed after the anneal process by a wet process such as dilute hydrofluoric acid or hot phosphoric acid.

Referring now to FIGS. 3F-3I simultaneously, cross-sectional views of the third semiconductor structure 300 are shown after forming a third epitaxial layer 210, selectively removing the second hardmask layer 114 and the second epitaxial layer 110, masking selected portions of the third epitaxial layer 210 and forming a third plurality of mandrel structures 230, according to an embodiment of the present disclosure.

The third epitaxial layer 210 may be formed off sidewalls of the second epitaxial layer 110 using an epitaxial growth process. In one or more embodiments, the third epitaxial layer 210 is made of silicon. The process of forming the third epitaxial layer 210 is similar to the one described above with reference to FIG. 2C. In one or more embodiments, the third epitaxial layer 210 can be grown to a thickness varying from approximately 50 nm to approximately 400 nm, although other thicknesses are within the contemplated scope of the invention. Preferably, the third epitaxial layer 210 is grown to a thickness varying from approximately 50 nm to approximately 200 nm.

After forming the third epitaxial layer 210, the second hardmask layer 114 and second epitaxial layer 110 can be removed from the third semiconductor structure 300 selective to silicon layers (i.e., third epitaxial layer 210). For example, the second hardmask layer 114 can be remove using a hot phosphoric acid etching. The second epitaxial layer 110 can be remove using, for example, a HCl chemistry in an epitaxial or RTCVD reactor.

The process continues by depositing and lithographically defining a photoresist layer on selected portions of the third epitaxial layer 210 to form a block mask 220; and selectively etching uncovered sections of the third epitaxial layer 210 using the block mask 220. As depicted in FIG. 3I, after selectively removing the uncovered sections of the third epitaxial layer 210, the block mask 220 can be removed using any photoresist striping method known in the art including, for example, plasma ashing.

So, portions of the third epitaxial layer 210 remaining above the buried dielectric layer 104 provide a third plurality of mandrel structures 230 (hereinafter “third mandrel structures”) that can be used as mold for nanoimprint lithology and/or optical waveguides in augmented reality displays.

For illustration purposes only, without intent of limitation, only two third mandrel structures 230 are shown in the figures. It should be noted that any number of third mandrel structures 230 can be formed in the second semiconductor structure 200 to satisfy design requirements. Although not depicted in the figures, the second mandrel structures 230 may have one or more different inclination angles s different from 90 degrees. Thus, in this embodiment, the second epitaxial layer 110 with a graded composition of Si₁₋ₓGeₓ allows accurately controlling a profile of the third mandrel structures 230.

According to an embodiment, a distance d (i.e., pitch) between third mandrel structures 230 may vary from approximately 200 nm to approximately 2000 nm. In another embodiment, the distance d between the third mandrel structures 230 may vary from approximately 400 nm to approximately 1000 nm, although other distances are within the contemplated scope of the invention.

Similar to the first mandrel structures 430, the third mandrel structures 230 may be covered with a thin layer of a conformal dielectric material 80 such as, for example, SiO₂ or SiN for stability and uniformity purposes. The thin layer of conformal dielectric material 80 may have a thickness varying from approximately 5 to approximately 20 nm, and ranges therebetween, and can be deposited using any conformal deposition process including, but not limited to, CVD, PECVD or ALD.

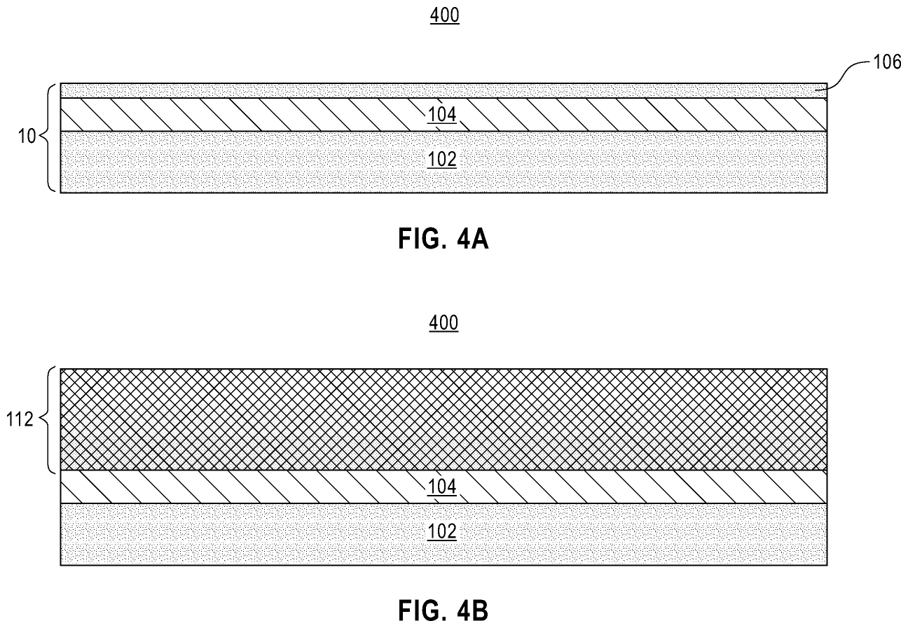

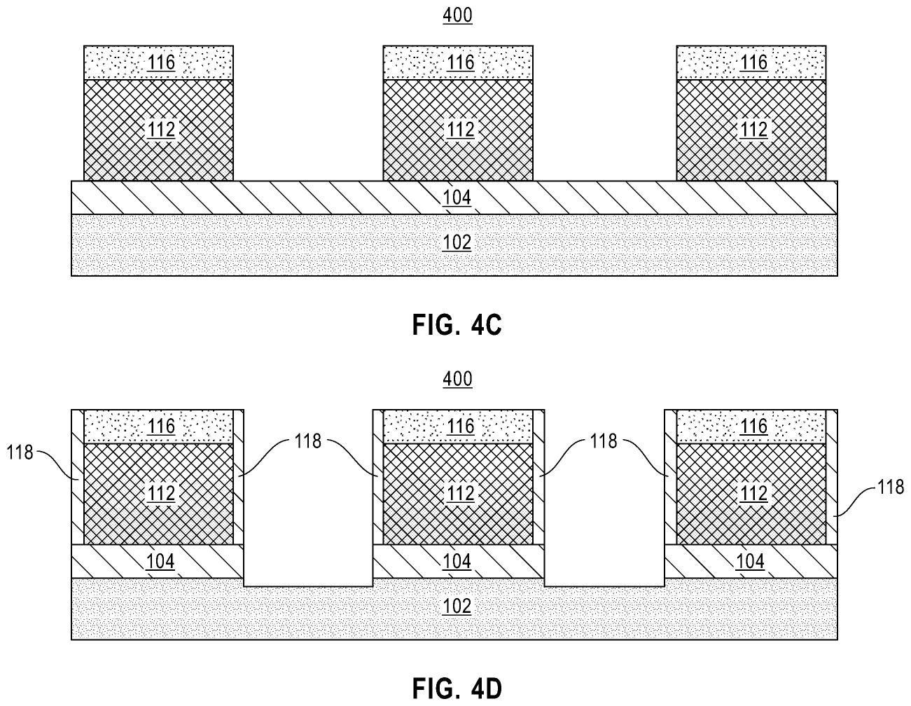

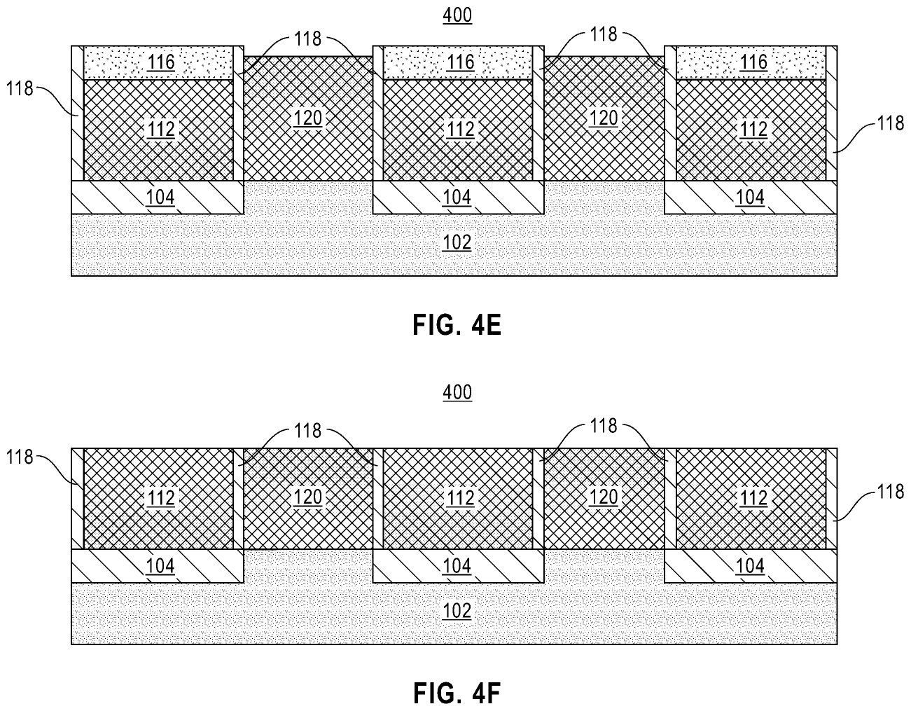

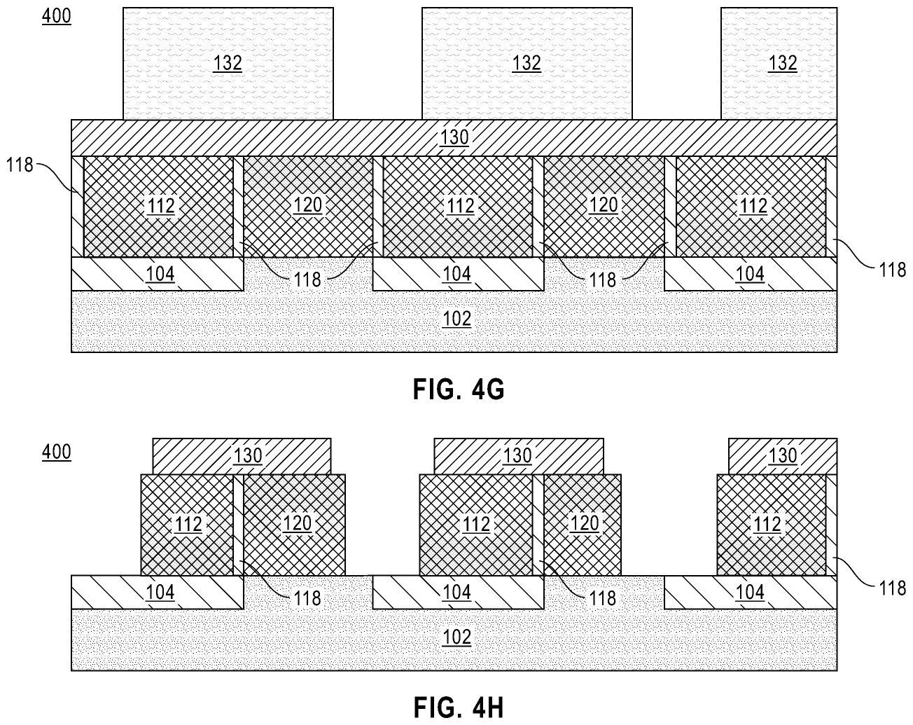

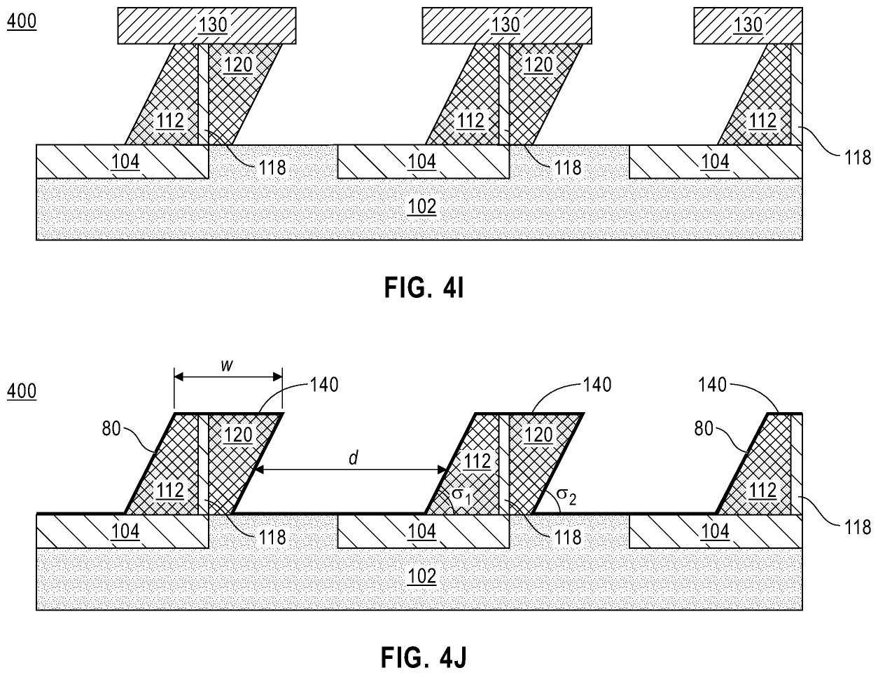

Another embodiment by which angled mandrel structures can be formed is described in detailed below by referring to the accompanying drawings in FIGS. 4A-4J.

Referring now to FIGS. 4A-4C simultaneously, cross-sectional views of a fourth semiconductor structure 400 are shown after forming a fourth epitaxial layer 112 on the substrate 10, forming a third hardmask layer 116 above the fourth epitaxial layer 112 and patterning the fourth epitaxial layer 112, according to an embodiment of the present disclosure.

The fabrication process depicted in FIGS. 4A-4C follows similar steps as those described above with reference to FIGS. 3A-3C. Accordingly, in this embodiment, the fabrication process starts with a substrate 10 including a thinned SOI layer 106. As previously described, an oxidation process followed by DHF cleaning can be used to substantially reduce a thickness of the SOI layer 106, as depicted in FIG. 4A. In an exemplary embodiment, a thickness of the SOI layer 106 may vary from approximately 1 nm to approximately 10 nm, and ranges therebetween. The thinned SOI layer 106 may function as a seed layer for the epitaxial growth process conducted to form the fourth epitaxial layer 112.

The process of epitaxially growing the fourth epitaxial layer 112 includes similar steps as those used to form the second epitaxial layer 110 described in FIG. 3B. Thus, similar to the second epitaxial layer 110 (FIG. 3B), the fourth epitaxial layer 112 is a graded SiGe layer.

According to an embodiment, the fourth epitaxial layer 112 includes a silicon-germanium layer that is linearly graded, e.g., Si₁₋ₓGeₓ. As a result, the concentration of germanium atoms is higher at the top end of the fourth epitaxial layer 112 and lower at the bottom end of the fourth epitaxial layer 112.

For example, in one particular embodiment, the fourth epitaxial layer 112 can have 100% Si and 0% Ge where it contacts the SOI layer 106. The fourth epitaxial layer 112 can be graded gradually, such that it has about 20% to 60% Si and 80% to 40% Ge at the top end of the fourth epitaxial layer 112. In one embodiment, the fourth epitaxial layer 112 includes a SiGe layer that is graded gradually from 100% Si at the bottom end to 30% Si at the top end of the fourth epitaxial layer 112.

In an exemplary embodiment, the fourth epitaxial layer 112 may be epitaxially grown to a thickness varying from approximately 100 nm and 500 nm, although other thicknesses are within the contemplated scope of the invention. Preferably, the fourth epitaxial layer 112 is grown to a thickness varying from approximately 300 nm and 400 nm.

A third hardmask layer 116 is formed above and in direct contact with the fourth epitaxial layer 112. Similar to the second hardmask layer 114 (FIG. 3C), the third hardmask layer 116 is composed of a dielectric material such as, for example, silicon dioxide, silicon nitride, silicon carbide, or a combination of such materials forming a multiple stack hardmask. Any known dielectric deposition process can be conducted to form the third hardmask layer 116. In an exemplary embodiment, a thickness of the third hardmask layer 116 may vary from approximately 10 nm to approximately 200 nm and ranges therebetween, although a thickness less than 10 nm and greater than 200 nm may be acceptable.

The fourth epitaxial layer 112 can then be etched selective to the third hardmask layer 116 and buried dielectric layer 104. For example, a RIE process can be used to selectively etch the fourth epitaxial layer 112, as depicted in FIG. 4C.

Referring now to FIG. 4D, a cross-sectional view of the fourth semiconductor structure 400 is shown after forming a sidewall spacer 118 and recessing the base substrate 102, according to an embodiment of the present disclosure.

In one or more embodiments, a spacer material can be deposited on the fourth semiconductor structure 400 using well-known spacer deposition methods. The spacer material deposits along sidewalls of the fourth epitaxial layer 112 and third hardmask layer 116 to form the sidewall spacer 118. The sidewall spacer 118 can be formed by deposition of a conformal spacer material using CVD or ALD followed by directional RIE of the deposited spacer material.

Non-limiting examples of various spacer materials for forming the sidewall spacer 118 may include conventional low-k materials such as SiO₂, SiOC, SiOCN, or SiBCN. Typically, a thickness of the sidewall spacer 118 may vary from approximately 5 nm to approximately 20 nm, and ranges therebetween.

The sidewall spacer 118 can be used as a mask to protect the fourth epitaxial layer 112 during a subsequent etching process. For instance, in this embodiment, an etching process (e.g., RIE) is conducted to expose an uppermost surface of the base substrate 102, as depicted in FIG. 4D. The exposed uppermost surface of the base substrate 102 composed of a silicon-containing material may be used as seed layer during epitaxial growth of a fifth epitaxial layer 120, as will be described in detail below.

Referring now to FIGS. 4E-4F, cross-sectional views of the fourth semiconductor structure 400 are shown after forming a fifth epitaxial layer 120 and conducting a planarization process, according to an embodiment of the present disclosure.

After etching the base substrate 102, a layer of a material similar to the one forming the base substrate 102 (i.e., silicon) can be formed within the recessed portion of the base substrate 102 depicted in FIG. 4D. So, the fifth epitaxial layer 120 can be epitaxially grown by using the (Si) base substrate 102 as the seed layer.

The process of epitaxially growing the fifth epitaxial layer 120 includes similar steps as those used to form the second epitaxial layer 110 described in FIG. 3B. However, in this embodiment, the fifth epitaxial layer 120 layer has a reverse SiGe gradient with respect to the adjacent fourth epitaxial layer 112. For instance, the fifth epitaxial layer 120 includes a silicon-germanium layer that is linearly graded, e.g., Si_{y}Ge_{1-y}, but the gradient varies in the opposite direction to the gradient of the fourth epitaxial layer 112. Thus, the fourth epitaxial layer 112 and the fifth epitaxial layer 120 have inverse SiGe gradients. Due to the different etch rates, mandrel structures of different inclination angles can be formed in the fourth semiconductor structure 400, as will be described in detail below.

According to an embodiment, the concentration of germanium atoms is higher at the bottom end of the fifth epitaxial layer 120 and lower at the top end of the fifth epitaxial layer 120. For example, in one particular embodiment, the fifth epitaxial layer 120 can have 100% Si and 0% Ge at the top end of the fifth epitaxial layer 120. The fifth epitaxial layer 120 can be graded gradually, such that it has about 20% to 60% Si and 80% to 40% Ge at the bottom end of the fifth epitaxial layer 120 where it contacts the base substrate 102. In one embodiment, the fifth epitaxial layer 120 includes a SiGe layer that is graded gradually from 100% Si at the top end to 30% Si at the bottom end of the fifth epitaxial layer 120.

In an exemplary embodiment, the fifth epitaxial layer 120 may be epitaxially grown to a thickness varying from approximately 100 nm and 500 nm, although other thicknesses are within the contemplated scope of the invention. Preferably, the fourth epitaxial layer 112 is grown to a thickness varying from approximately 300 nm and 400 nm.

After forming the fifth epitaxial layer 120, a planarization process such as a chemical mechanical polishing (CMP) can be conducted on the fourth semiconductor structure 400 to remove and planarize excess materials. After the planarization process top surfaces of the fourth epitaxial layer 112, sidewall spacer 118 and fifth epitaxial layer 120 are substantially coplanar.

Referring now to FIGS. 4G-4H, cross-sectional views of the fourth semiconductor structure 400 are shown after forming a fourth hardmask layer 130 and patterning the fourth and fifth epitaxial layers 112, 120, according to an embodiment of the present disclosure.

In one or more embodiments, the fourth hardmask layer 130 is formed in similar ways and includes analogous materials as the second and third hardmask layers 114, 116. A photoresist layer 132 can be formed above the fourth hardmask layer 130, as depicted in FIG. 4G. As known by those skilled in the art, the process of patterning the fourth and fifth epitaxial layers 112, 120 depicted in FIG. 4H typically involves exposing a pattern on the photoresist layer 132 and transferring the pattern to the fourth hardmask layer 130 and to the fourth and fifth epitaxial layers 112, 120 using known lithography and RIE processing.

After patterning the fourth and fifth epitaxial layers 112, 120, the photoresist layer 132 can be removed using any photoresist striping method known in the art including, for example, plasma ashing.

Referring now to FIGS. 4I-4J, cross-sectional views of the fourth semiconductor structure 400 are shown after selectively recessing the fourth and fifth epitaxial layers 112, 120 and removing the fourth hardmask layer 130, according to an embodiment of the present disclosure.

The process continues by selectively recessing the fourth epitaxial layer 112 and the fifth epitaxial layer 120 with respect to silicon using, for example, a high temperature HCl etching in RTCVD reactor. Selective etching of the fourth epitaxial layer 112 versus silicon etches faster Si₁₋ₓGeₓ layers at the top end of the fourth epitaxial layer 112 having a high Ge content (typically ≥30%), while selective etching of the fifth epitaxial layer 120 versus silicon etches faster Si_{y}Ge_{1-y} layers at the bottom end of the fifth epitaxial layer 120 having a high Ge content (typically ≥30%). The etch rate difference causes the fourth epitaxial layer 112 and fifth epitaxial layer 120 to have different angle profiles.

After the etching process, the fourth hardmask layer 130 can be selectively removed from the fourth semiconductor structure 400 using, for example, a hot phosphoric acid etching (e.g., the fourth hardmask layer 130 includes SiN) or DHF cleaning (e.g., the fourth hardmask layer 130 includes an oxide material).

Accordingly, in the depicted embodiment, remaining portions of the fourth epitaxial layer 112 and fifth epitaxial layer 120 separated by the sidewall spacer 118 provide a fourth plurality of mandrel structures 140 (hereinafter “fourth mandrel structures”) that can be used as a mold for nanoimprint lithography and/or as optical waveguides in augmented reality displays.

For illustration purposes only, without intent of limitation, only three fourth mandrel structures 140 are shown in the figures. It should be noted that any number of fourth mandrel structures 140 can be formed in the fourth semiconductor structure 400 to satisfy design requirements.

It should also be noted that an inclination angle (with respect to the horizontal plane) of the fourth mandrel structures 140 can be tailored to satisfy design requirements by adjusting the concentration of germanium atoms in the fourth epitaxial layer 112 and fifth epitaxial layer 120. The fourth mandrel structures 140 may have one or more different inclination angles s₁, s₂ different from 90 degrees. Specifically, in some embodiments, a first inclination angle s₁ of the fourth epitaxial layer 112 can be the same or substantially similar to a second inclination angle s₂ of the fifth epitaxial layer 120. In other embodiments, the first inclination angle s₁ of the fourth epitaxial layer 112 can be different than a second inclination angle s₂ of the fifth epitaxial layer 120 producing a mandrel structure with an asymmetric profile.

According to an embodiment, a distance d (i.e., pitch) between fourth mandrel structures 140 may vary from approximately 50 nm to approximately 2000 nm. In another embodiment, the distance d between the fourth mandrel structures 140 may vary from approximately 200 nm to approximately 1000 nm, although other distances are within the contemplated scope of the invention.

Thus, in this embodiment, an inclination angle s₁ of the fourth epitaxial layer 112 can be different that an inclination angle s₂ of the fifth epitaxial layer 120 with respect to the horizontal plane. Stated differently, the inclination angle of a first side of at least one fourth mandrel structure 140 can be independently controlled from the inclination angle of a second side of the at least one fourth mandrel structure 140 (opposing the first side) by changing the concentration of germanium atoms. For example, the fourth mandrel structures 140 may have a 45 degrees angle on both sides, or a 30 degrees angle on one side and 60 degrees angle on the other side. The width w of the fourth mandrel structures 140 is determined by the SiGe gradient and the corresponding etch rate.

Alternatively, or additionally, the fourth mandrel structures 140 may be covered with a thin layer of a conformal dielectric material 80 such as, for example, SiO₂ or SiN for stability and uniformity purposes. The thin layer of conformal dielectric material 80 may have a thickness varying from approximately 5 to approximately 20 nm, and ranges therebetween, and can be deposited using any conformal deposition process including, but not limited to, CVD, PECVD or ALD.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a plurality of mandrel structures disposed above and in contact with a substrate, each of the plurality of mandrel structures extending outwardly at an inclination angle with respect to a surface plane of the substrate that is different from 90 degrees; and
a template structure for an imprint mask formed by the plurality of mandrel structures.

2. The semiconductor structure of claim 1, further comprising:
a layer of a conformal dielectric material covering the plurality of mandrel structures, the layer of conformal dielectric material providing stability and uniformity to the plurality of mandrel structures.

3. The semiconductor structure of claim 1, wherein each of the plurality of mandrel structures has a similar inclination angle with respect to the substrate.

4. The semiconductor structure of claim 1, wherein each of the plurality of mandrel structures has a different inclination angle with respect to the substrate.

5. The semiconductor structure of claim 1, wherein each of the plurality of mandrel structures includes a semiconductor material.

6. The semiconductor structure of claim 5, wherein the semiconductor material includes boron-doped silicon.

7. The semiconductor structure of claim 5, wherein a width of each of the plurality of mandrel structures is determined by a depth of an angled ion implantation.

8. The semiconductor structure of claim 5, wherein the semiconductor material includes an epitaxially grown material.

9. The semiconductor structure of claim 8, wherein the epitaxially grown material includes silicon-germanium.

10. The semiconductor structure of claim 8, wherein the epitaxially grown material includes silicon.

11. The semiconductor structure of claim 8, wherein the width of each of the plurality of mandrel structures is determined by a width of the epitaxially grown material.

12. The semiconductor structure of claim 1, wherein each of the plurality of mandrel structures includes:
a first side including a first graded semiconductor material;
a second side including a second graded semiconductor material; and
a sidewall spacer vertically separating the first side from the second side.

13. The semiconductor structure of claim 12, wherein the first graded semiconductor material includes a graded silicon-germanium layer, wherein a germanium concentration in the graded silicon-germanium layer is higher at a top end of the graded silicon-germanium layer and lower at a bottom end of the graded silicon-germanium layer.

14. The semiconductor structure of claim 13, wherein the second graded semiconductor material includes another graded silicon-germanium layer having an inverse gradient, wherein the germanium concentration in the another graded silicon-germanium layer is lower at a top end of the another graded silicon-germanium layer and higher at a bottom end of the another graded silicon-germanium layer.

15. A method of forming a semiconductor structure, comprising:
forming a plurality of mandrel structures disposed above and in contact with a substrate, each of the plurality of mandrel structures extending outwardly at an inclination angle with respect to a surface plane of the substrate that is different from 90 degrees, the plurality of mandrel structures providing a template structure for an imprint mask.

16. The method of claim 15, further comprising:
forming a layer of a conformal dielectric material to cover the plurality of mandrel structures, the layer of conformal dielectric material providing stability and uniformity to the plurality of mandrel structures.

17. The method of claim 15, wherein each of the plurality of mandrel structures has a similar inclination angle with respect to the substrate.

18. The method of claim 15, wherein each of the plurality of mandrel structures has a different inclination angle with respect to the substrate.

19. The method of claim 15, wherein forming the plurality of mandrel structures above the substrate comprises:
forming a mask layer above a silicon-containing layer of the substrate;
using a first tapered etching process, patterning the silicon-containing layer to achieve a plurality of sections of the silicon-containing layer with an inverse tapered profile;
conducting an angled ion implantation process on a first side of each section of the silicon-containing layer to form a doped region along the first side of each section of the silicon-containing layer; and
selectively removing the silicon-containing layer from the substrate, wherein remaining doped regions provide the plurality of mandrel structures.

20. The method of claim 19, wherein the doped region includes boron-doped silicon.

21. The method of claim 19, wherein a width of each of the plurality of mandrel structures is determined by a depth of the angled ion implantation process.

22. The method of claim 19, wherein forming the plurality of mandrel structures above the substrate comprises:
forming a first hardmask layer above the silicon-containing layer of the substrate;
using the tapered etching process, patterning the silicon-containing layer to achieve the plurality of sections of the silicon-containing layer with the inverse tapered profile;
epitaxially growing a silicon-germanium layer above each side of the plurality of sections of the silicon-containing layer;
selectively removing, the first hardmask and the silicon-containing layer with respect to the silicon-germanium layer, wherein a plurality of angled silicon-germanium layers remain on the substrate;
using a first block mask, covering selected angled silicon-germanium layers; and
removing uncovered angled silicon-germanium layers from the substrate, wherein remaining angled silicon-germanium layers provide the plurality of mandrel structures.

23. The method of claim 19, wherein forming the plurality of mandrel structures above the substrate comprises:
thinning the silicon-containing layer of the substrate;
epitaxially growing a first graded silicon-germanium layer above the thinned silicon-containing layer of the substrate;
forming a second hardmask layer and patterning the first graded silicon-germanium layer;
selectively recessing the first graded silicon-germanium layer;
conducting a high temperature anneal process;
epitaxially growing a silicon layer above opposite sides of the first graded silicon-germanium layer to form angled silicon layers;
removing the second hardmask layer and the first graded silicon-germanium layer selective to the angled silicon layers;
using a second block mask, covering selected angled silicon layers; and
removing uncovered angled silicon layers from the substrate, wherein remaining angled silicon layers provide the plurality of mandrel structures.

24. The method of claim 19, wherein forming the plurality of mandrel structures above the substrate comprises:
thinning the silicon-containing layer of the substrate;
epitaxially growing a second graded silicon-germanium layer above the thinned silicon-containing layer of the substrate;
forming a third hardmask layer and patterning the second graded silicon-germanium layer;
forming a sidewall spacer along opposite sidewalls of the patterned second graded silicon-germanium layer;
epitaxially growing a third graded silicon-germanium layer within a space located between two second graded silicon-germanium layers;
removing the third hardmask layer and planarizing top surfaces of the second graded silicon-germanium layer, sidewall spacer and third graded silicon-germanium layer;
forming a fourth hardmask layer and patterning the second graded silicon-germanium layer and the third graded silicon-germanium layer, wherein remaining portions of the second graded silicon-germanium layer and the third graded silicon-germanium layer separated by the sidewall spacer provide the plurality of mandrel structures; and
removing the third hardmask layer.

25. The method of claim 24, wherein a germanium concentration in the second graded silicon-germanium layer is higher at a top end of the second graded silicon-germanium layer and lower at a bottom end of the second graded silicon-germanium layer, and a germanium concentration in the third graded silicon-germanium layer is lower at a top end of the third graded silicon-germanium layer and higher at a bottom end of the third graded silicon-germanium layer.
